(19) United States
(12) Patent Application Publication
(10) Pub. No.: US 2010/0132769 A1
(43) Pub. Date: Jun. 3, 2010

(54) SOLAR CANOPY SUPPORT SYSTEM

(75) Inventors: David S. Potter, Danville, CA (US); Jeff P. Munoz, San Francisco, CA (US)

Correspondence Address: CHEVRON CORPORATION, P.O. BOX 6006, SAN RAMON, CA, 94583-0806, US

(73) Assignee: Chevron U.S.A. Inc.

(21) Appl. No.: 12/604,947

(22) Filed: Oct. 23, 2009

(51) Int. Cl. H01L 31/042; A47F 7/00; B23P 11/00

(52) U.S. Cl. 136/251; 211/41.1; 29/890.033; 29/428

(57) ABSTRACT

The solar canopy support system has at least two beam support columns. Each beam support column has a first end connected to a ground surface and extends substantially vertically along a longitudinal axis from the first end to a second end. There is also a zee channel support beam connected at the second end of each beam support column. The zee channel support beam includes a longitudinal axis within about 0 degrees to about 30 degrees of perpendicular to the longitudinal axis of each beam support column. There are also two or more zee channels. Each zee channel has a first end connected to an upper portion of one zee channel support beam and has a second end connected to an upper portion of another zee channel support beam. Each zee channel includes a longitudinal axis substantially perpendicular to the longitudinal axis of each zee channel support beam; at least one solar power array connected on an upper portion of at least two zee channels.

### I. COPYRIGHT NOTICE AND AUTHORIZATION

This patent document contains material which is subject to copyright protection.

© Copyright 2009. Chevron Energy Solutions. All rights reserved.

With respect to this material which is subject to copyright protection. The owner, Chevron Energy Solutions has no objection to the facsimile reproduction by any one of the patent disclosure, as it appears in the Patent and Trademark Office patent files or records of any country, but otherwise reserves all rights whatsoever.

### II. FIELD OF THE INVENTION

This invention relates to system and method for support of a solar canopy.

### III. BACKGROUND OF THE INVENTION

Solar energy is a clean, renewal energy source. Photo-electro voltaic cell technology is increasing rapidly and makes installation of solar collector panels housing the photo-electro voltaic cells more and more economically feasible. Beyond the photo-electro voltaic cell technology itself are the problems of placement and support of the solar collector panels. Large numbers of solar collector panels must be assembled in series to achieve useful power production. In remote areas these may be placed on the ground without interfering with land use. In more developed areas, it is desirable to place the solar collector panels such that the land may also be used for other purposes, e.g., for parking lots, school/office hallways, playgrounds, or sports fields. To achieve this requires an elevated structure to support the solar collector panels.

Prior known systems for elevated structures for supporting the solar collector panels are inefficient and overly expensive since they require excessive amounts of materials, particularly steel support elements. Also, known systems take an excessive amount of time to install since welding together of the components is required on site.

It is desirable to have a method and system which overcomes the deficiencies of known systems. The instant invention provides such a solution.

### IV. SUMMARY OF THE INVENTION

The invention includes a solar canopy support system comprising: at least two substantially horizontally disposed zee channel support beams for supporting at least two zee channels, and at least two zee channels for supporting at least one solar power array and fixedly attached to the at least two zee channel support beams, each zee channel having a first end disposed at an upper portion of one zee channel support beam and having a second end disposed at an upper portion of another zee channel support beam, each zee channel comprising a longitudinal axis substantially perpendicular to the longitudinal axis of each zee channel support beam.

In another embodiment, the invention includes a solar canopy support system comprising: at least two beam support columns, each beam support column having a first end connected to a ground surface and extending substantially vertically along a longitudinal axis from the first end to a second end; a zee channel support beam disposed at the second end of each beam support column, the zee channel support beam comprising a longitudinal axis within about 0 degrees to about 30 degrees of perpendicular to the longitudinal axis of each beam support column; at least two zee channels, each zee channel having a first end disposed at an upper portion of one zee channel support beam and having a second end disposed at an upper portion of another zee channel support beam, each zee channel comprising a longitudinal axis substantially perpendicular to the longitudinal axis of each zee channel support beam; and at least one solar power array disposed on an upper portion of at least two zee channels.

In another embodiment the invention includes a method of mounting a solar canopy comprising: affixing at least two beam support columns to a ground surface, each beam support column having a first end connected to the ground surface and extending substantially vertically along a longitudinal axis from the first end to a second end; affixing a zee channel support beam to the second end of each beam support column, the zee channel support beam comprising a longitudinal axis within about 0 degrees to about 30 degrees of perpendicular to the longitudinal axis of each beam support column; affixing at least two zee channels to the at least two zee channel support beams, each zee channel having a first end disposed at an upper portion of one zee channel support beam and having a second end disposed at an upper portion of another zee channel support beam, each zee channel comprising a longitudinal axis substantially perpendicular to the longitudinal axis of each zee channel support beam; and affixing at least one solar power array to an upper portion of the at least two zee channels.

These and other features and advantages of the present invention will be made more apparent through a consideration of the following detailed description of a preferred embodiment of the invention. In the course of this description, frequent reference will be made to the attached drawings.

### V. BRIEF DESCRIPTION OF THE DRAWINGS

FIG. 1 is a top perspective view of one embodiment of the present invention.

FIG. 2 is a bottom perspective view of one embodiment of the present invention.

FIG. 3 is an exploded perspective view of one embodiment of the present invention.

FIG. 4 is a top perspective view of the embodiment of FIG. 1 showing the support structure.

FIG. 5 is a top perspective view in one embodiment of the support bollard and column of the embodiment of FIG. 1.

FIG. 6 is a top perspective view in one embodiment of the rebar structure of the support bollard of the embodiment of FIG. 1.

FIG. 7 is a top perspective view in one embodiment of the rebar structure of the support bollard with attached beam support columns column of the embodiment of FIG. 1.

FIG. 8 shows a bottom perspective view in one embodiment of the solar array support structure of the embodiment of FIG. 1.

FIGS. 9A and 9B show a bottom and top perspective view, respectively, in one embodiment of a support assembly of the invention.

FIGS. 10A and 10B show cross-sectional perspective views in one embodiment of a clip assembly for attaching solar panels to zee channels, at the end of and in the middle of the solar canopy array, respectively, in the embodiment of FIG. 1.

FIGS. 11A and 11B show perspective views of one embodiment of an anchor member for attaching solar panels to zee channels in one embodiment of FIG. 1.

FIGS. 12A and 12B show perspective views in one embodiment of a head member of a clip assembly for attaching solar panels, at a middle section of and at an end section of the solar canopy array, respectively, to zee channels in the embodiment of FIG. 1.

FIGS. 13A and 13B show perspective views in one embodiment of a clip assembly for attaching solar panels to zee channels, at a middle section of and at an end section of the solar canopy array, respectively, in the embodiment of FIG. 1.

FIGS. 14A and 14B show a top perspective view in another embodiment of an anchor member of a clip assembly for attaching solar panels to zee channels in the embodiment of FIG. 1.

FIGS. 15A and 15B show perspective views in another embodiment of a head member of a clip assembly for attaching solar panels, at a end section of and at a mid-section of the solar canopy array, respectively, to zee channels in the embodiment of FIG. 1.

### VI. DETAILED DESCRIPTION OF PREFERRED EMBODIMENTS

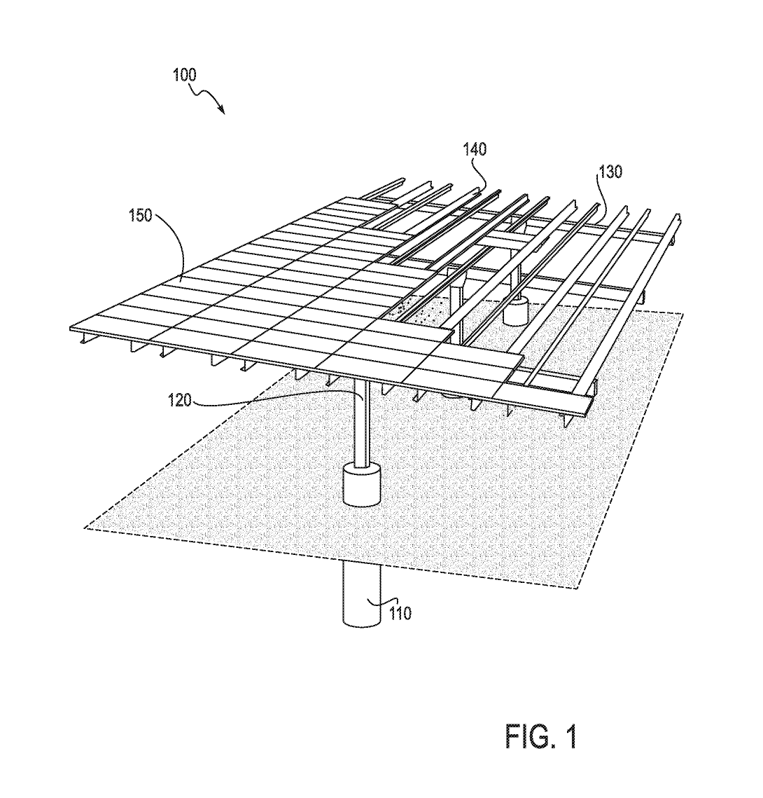

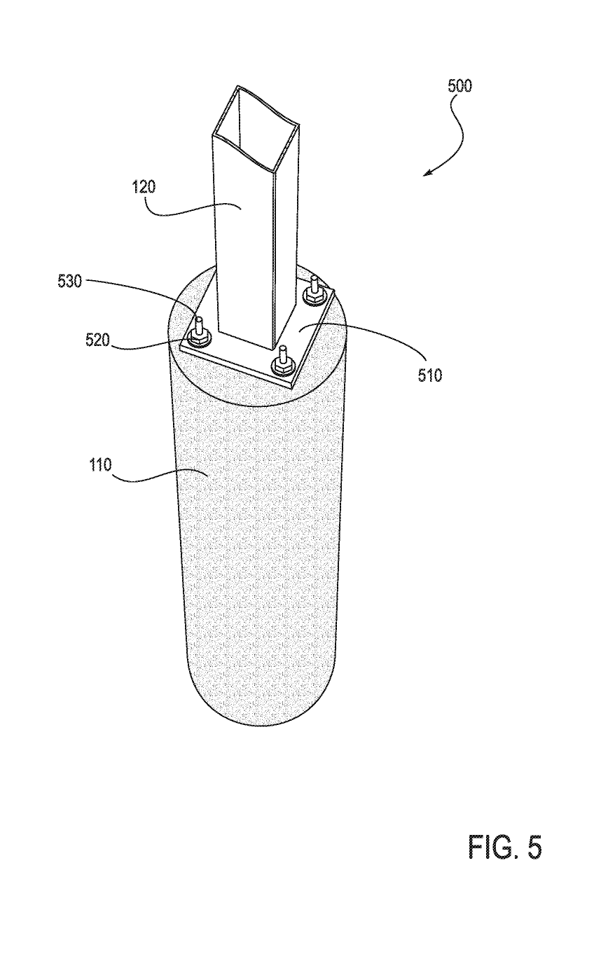

FIG. 1 is a top perspective view of one embodiment of the present invention. Solar canopy support system 100 is shown—both above and below grade level (shown as gray-filled plane). Reinforced concrete bollard 110 rests in the ground and provides the support for beam support column 120. Beam support column 120 is attached to reinforced concrete bollard 110 by any known method, by embedding a lower portion of beam support column 120 in the concrete of beam support column 120 while still wet or placing it in a suitable hole and then pouring the concrete around it, or by embedding bolts in the reinforced concrete bollard 110 with protruding ends which permit attachment of the beam support column 120 by bolting, which will be described in more detail with reference to FIGS. 5-7.

The beam support columns 120 supports zee channel support beams 130. The zee channel support beam 130 supports at least two zee channels 140. This provides the solar canopy support system for supporting a solar power array 150. The solar power array is a plurality of solar panels which may be attached to the zee channels 140 by any method now known or later developed.

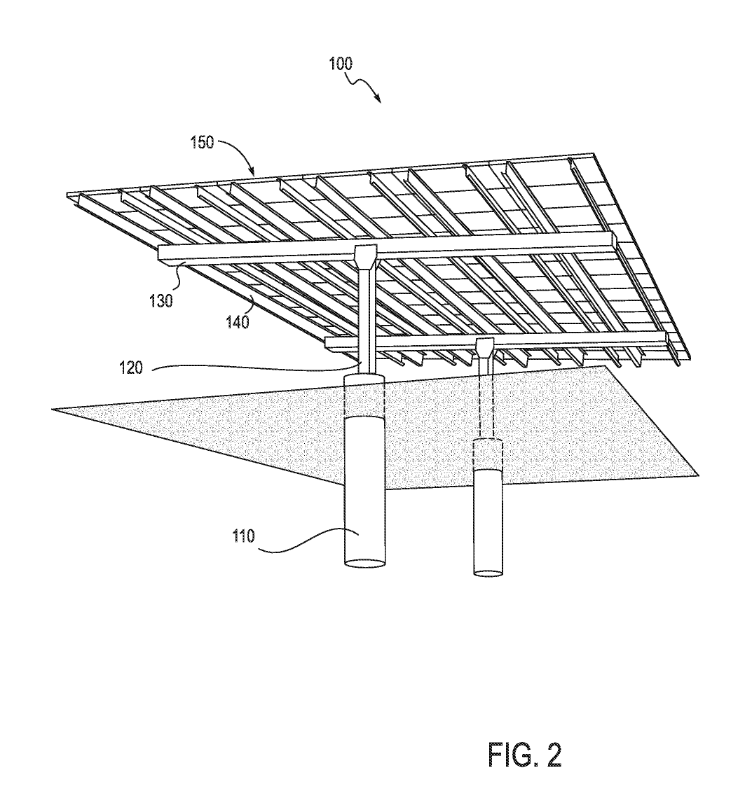

FIG. 2 is a bottom perspective view of one embodiment of the present invention. In a preferred embodiment a pair of zee channels 140 is affixed to a pair of sub-structure assemblies comprising reinforced concrete bollards 110, beam support columns 120, and zee channel support beams 130. Beam support columns 120, in one embodiment are comprised of steel cylindrical columns, or steel I-beams. Zee channel support beams 130 in one embodiment are comprised of steel I-beams or 4-sided beams.

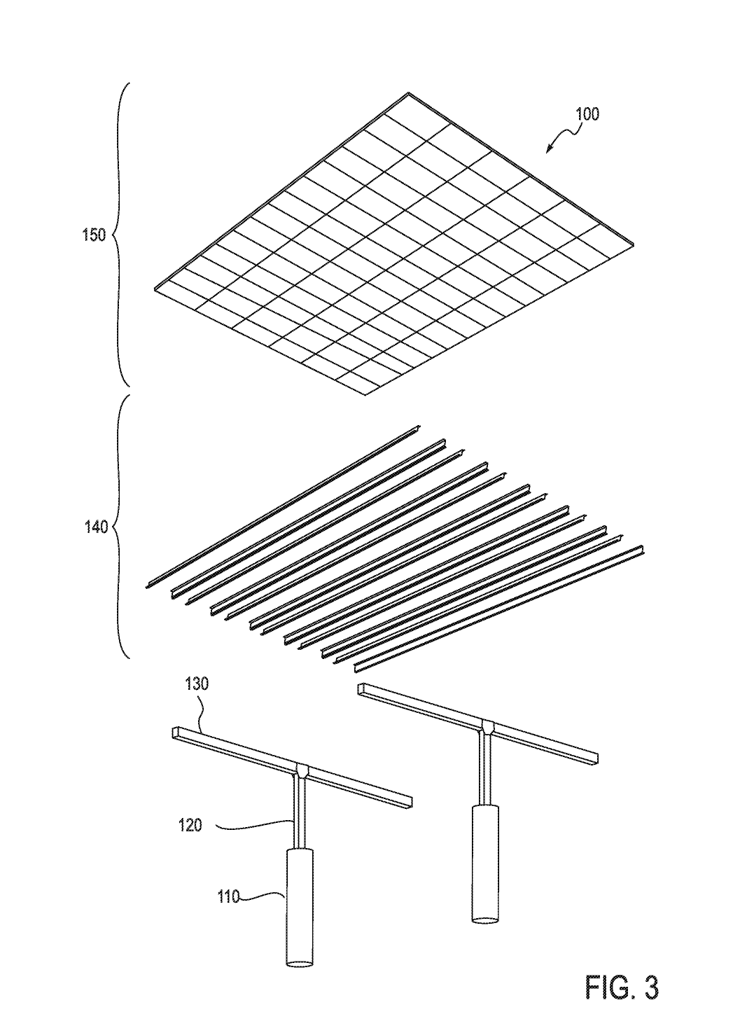

FIG. 3 is an exploded perspective view of one embodiment of the present invention.

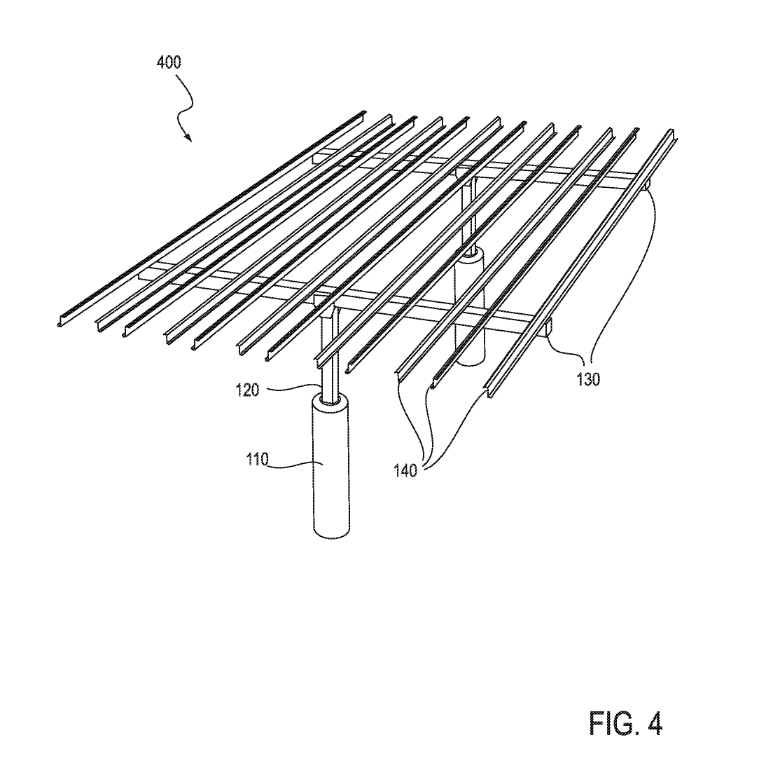

FIG. 4 is a top perspective view of the embodiment of FIG. 1 showing the support structure 400. In a preferred embodiment, the pairs of zee channels 140 are placed in opposite orientations. That is, when looking at end section, one of the pair of zee channels 140 shows the letter “Z” and the other of the pair of zee channels 140 shows a backwards letter “Z”. In a preferred embodiment the zee channel is constructed of any suitable material, e.g., galvanized steel/sheet metal, and has a gauge from about 11 to about 13. The maximum run lengths of each zee channel will depend on, e.g., ground conditions, weight of solar panels, and number of zee channels. Typical run, lengths in one embodiment, is from about 11 feet to about 29 feet.

FIG. 5 is a top perspective view in one embodiment of the reinforced concrete bollards 110 and beam support columns 120 of the embodiment of FIG. 1. In this embodiment the beam support columns 120 are removably attached to the reinforced concrete bollards 110 by bolting the beam support columns 120 to the reinforced concrete bollards 110 via bolts 530 embedded in the concrete of the bollards 110 and flanges 510 integral with the beam support columns 120. This reduces construction costs since the reinforced concrete bollards 110 installation and the beam support columns 120 can be done in succession, e.g., by different crews and/or on different days in a assembly line fashion.

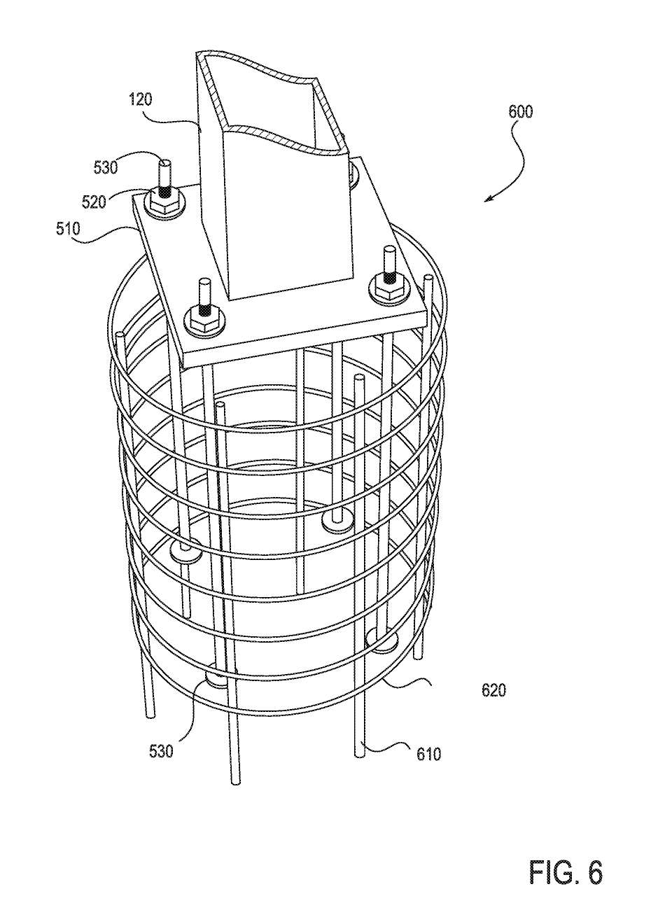

FIG. 6 is a top perspective view in one embodiment of the rebar structure 600 of the reinforced concrete bollards 110 of the embodiment of FIG. 1. The helix rebars 620 and vertical rebar 610, together with threaded bolts 530 are embedded within the concrete of the bollards. They provide structural strength to resist both compression and tension forces. Compression forces exist primarily due to the weight of the overall solar canopy support structure 100 (FIG. 1). Tension forces are significant because of upward pressure caused by wind against the large flat surface made by the solar power array 150 (FIG. 1). Construction of the rebar configuration to provide adequate support will vary, e.g., with soil conditions, slope, and prevailing weather at the site. Exemplary construction factors and, e.g., depth, for different soil conditions are shown in the following table.

| | | SOIL PARAMETERS | | | | |
|---|---|---|---|---|---|---|
| | | ASSUMED SOIL VALUES | | | | |
| | | | | | | ULTIMATE VERTICAL |
| | SOIL | COHESION | PHI | UNIT WEIGHT | ULTIMATE PASSIVE | CAPACITY Q |
| CASE | DESCRIPTION | (PSF) | (DEGREES) | (PCF) | RESISTANCE | (kl pr) |
| 1 | SOFT CLAY | 300 | 0 | 100 | 600 psf | 0.94xDxL |
| 2 | FIRM CLAY | 700 | 0 | 120 | 1,400 psf | 2.2xDxL |
| 3 | HARD CLAY | 1200 | 0 | 120 | 2,400 psf | 3.09xDxL |
| 4 | MEDIUM DENSE SAND | 0 | 34 | 115 | 400 psf | 0.046xDxL² |
| 5 | VERY HARD CLAY | 2000 | 0 | 125 | 2,500 psf | 3.46xDxL |
| 6 | ROCK | 3000 | 35 | 130 | 2,500 psf | 7.07xDxL |

Soil Parameters are to be verified for each site by a Registered Geotechnical Engineer

| | 2007 CBC SESMIC PARAMETERS | | | | | | | | | | | | | | FOOTING DEPTH |
|---|---|---|---|---|---|---|---|---|---|---|---|---|---|---|---|
| | SITE | SOIL PROFILE | | | | | | | | | | | | | UP TO 27′ SPAN |
| CASE | CLASS¹ | NAME¹ | ^{S}S^{(g)2} | ^{S}1^{(g)3} | ^{F}S⁴ | ^{F}a⁴ | ^{F}v⁵ | ^{S}MS⁶ | ^{S}M1⁷ | ^{S}DS⁸ | ^{S}D1⁹ | V | ^{C}S | R | “H” |
| 1 | E | SOFT SOIL | 2.85 | 1.30 | 0.90 | 0.90 | 2.40 | 2.57 | 3.12 | 1.71 | 2.08 | 1.19 W | 1.19 | 2 | 18′ |
| 2 | E | SOFT SOIL | 2.85 | 1.30 | 0.90 | 0.90 | 2.40 | 2.57 | 3.12 | 1.71 | 2.08 | 1.19 W | 1.19 | 2 | 12′ |
| 3 | D | STIFF SOIL | 2.85 | 1.30 | 1.00 | 1.00 | 1.50 | 2.85 | 1.95 | 1.90 | 1.30 | 1.19 W | 1.19 | 2 | 10′ |
| 4 | D | STIFF SOIL | 2.85 | 1.30 | 1.00 | 1.00 | 1.50 | 2.85 | 1.95 | 1.90 | 1.30 | 1.19 W | 1.19 | 2 | 18′ |
| 5 | C | VERY DENSE | 2.85 | 1.30 | 1.00 | 1.00 | 1.30 | 2.85 | 1.69 | 1.71 | 2.08 | 1.19 W | 1.19 | 2 | 10′ |
| | | SOIL/SOFT | | | | | | | | | | | | | |
| | | ROCK | | | | | | | | | | | | | |
| 6 | B | ROCK | 2.85 | 1.30 | 1.00 | 1.00 | 1.00 | 2.85 | 1.30 | 1.90 | 0.87 | 1.19 W | 1.19 | 2 | 10′ |

¹Refers to Section 1613A.5.2, Table 1613A.5.2 for selection criteria for Site Class and Soil Profile Name of the 2007 CBC.
²Based on FIG. 22-3, maximum considered earthquake ground motion for Region 1 or 0.2 sec; Spectral Response acceleration (5% of critical damping), Site Class B, pages 214 and 215 of ASCE -05.
³ Eased on FIG. 22-4. Maximum considered earthquake ground motion for region 1 of 1.0 sec spectral response acceleration (5% of critical damping), Site Class B, pages 216 and 217 of ASCE 7-05.
⁴Based on Section 1613A.5.3, Table 1613A.5.3(1) of the 2007 CBC.
⁵Based on Section 1613A.5.3, Table 1613A.5.3(2) of the 2007 CBC.
⁶Based on Section 1613A.5.3, Equation 16A-37 of the 2007 CBC.
⁷Based on Section 1613A.5.3, Equation 16A-38 of the 2007 CBC.
⁸Based on Section 1613A.5.4, Equation 16A-39 of the 2007 CBC.
⁹Based on Section 1613A.5.4, Equation 16A-40 of the 2007 CBC.

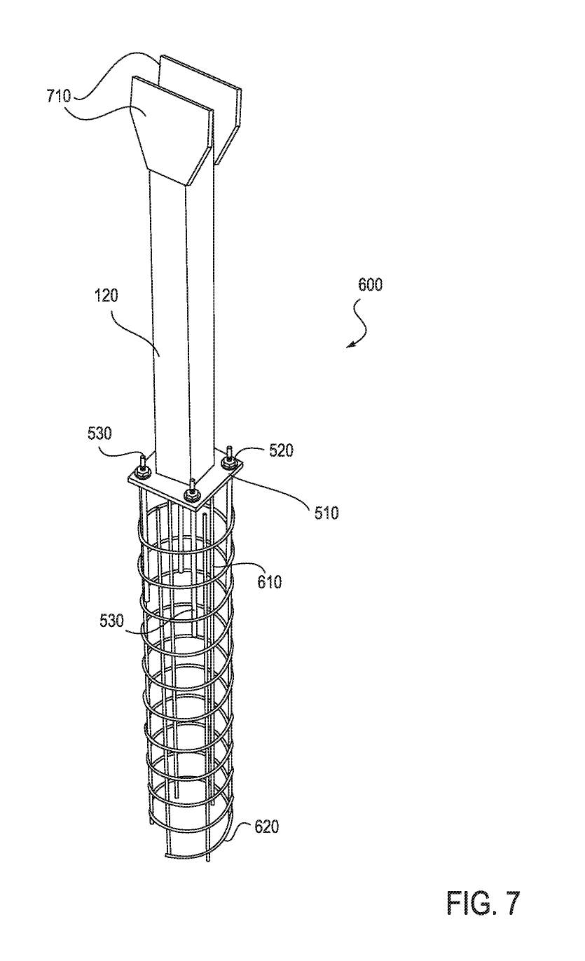

FIG. 7 is a top perspective view in one embodiment of the rebar structure of the reinforced concrete bollards 110 with attached beam support columns 120 of the embodiment of FIG. 1. In a preferred embodiment a pair of flanges 710 extends upward from, and integral with, the top portion of the beam support columns 120. Flanges 710 provide a channel for receiving the zee channel support beams 130. The zee channel support beams 130 are preferably fixed by bolts through the flanges 710 into the zee channel support beams 130 (pre-drilled or cast holes in flanges 710 not shown). This reduces construction time compared, e.g., to welding.

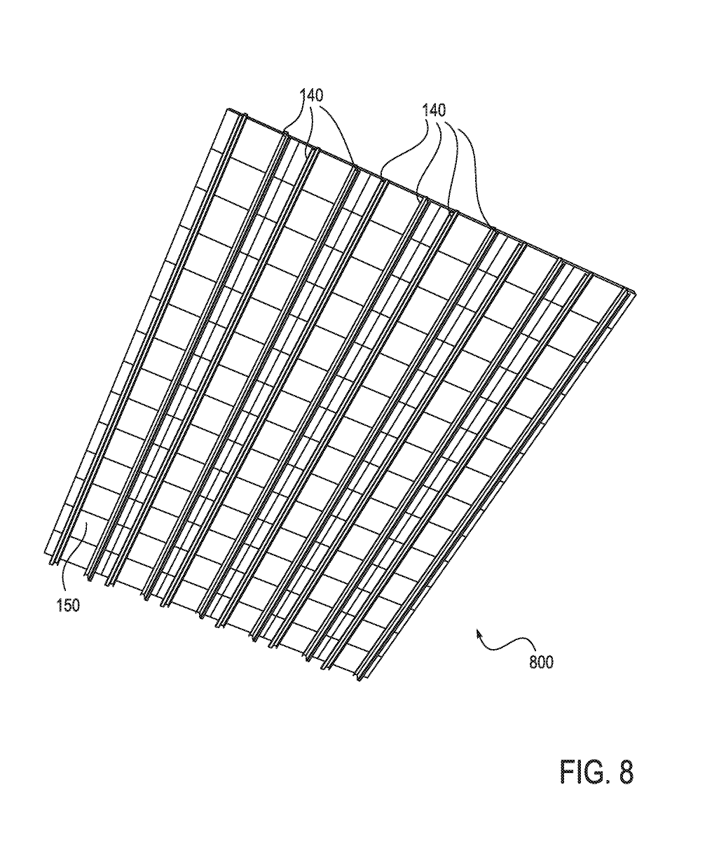

FIG. 8 shows a bottom perspective view in one embodiment of the solar array support structure of the embodiment of FIG. 1. A plurality of pairs of oppositely oriented zee channels 140 supports a plurality of solar panels, i.e., solar power array 150.

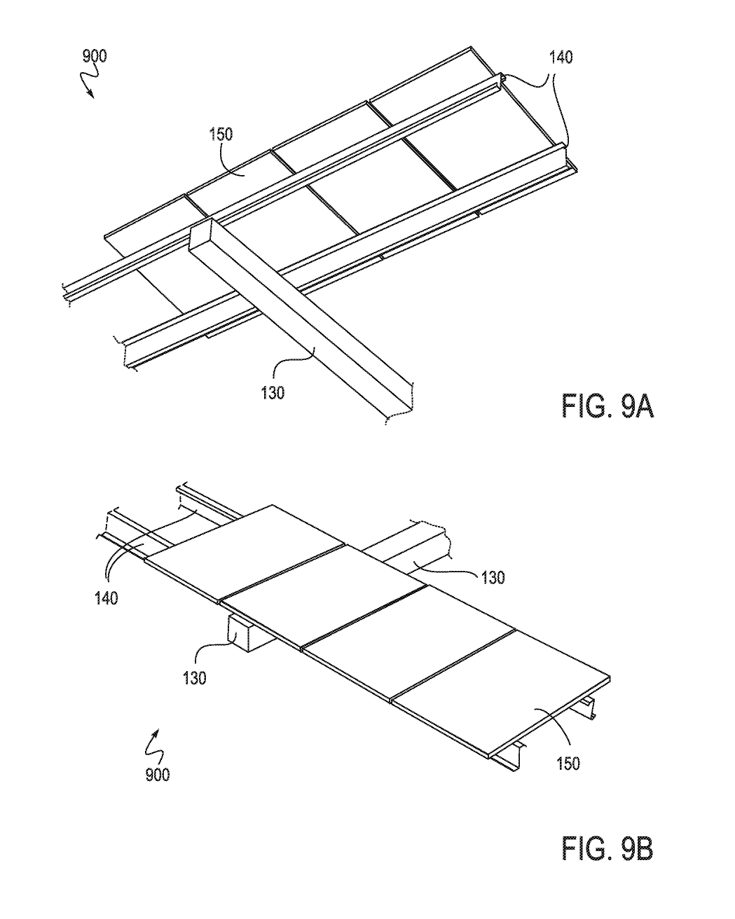

FIGS. 9A and 9B show a bottom and top perspective view, respectively, in one embodiment of a support assembly of the invention. Zee channel support beam 130 supports at least two zee channels 140. Zee channels 140 support a solar power array 150.

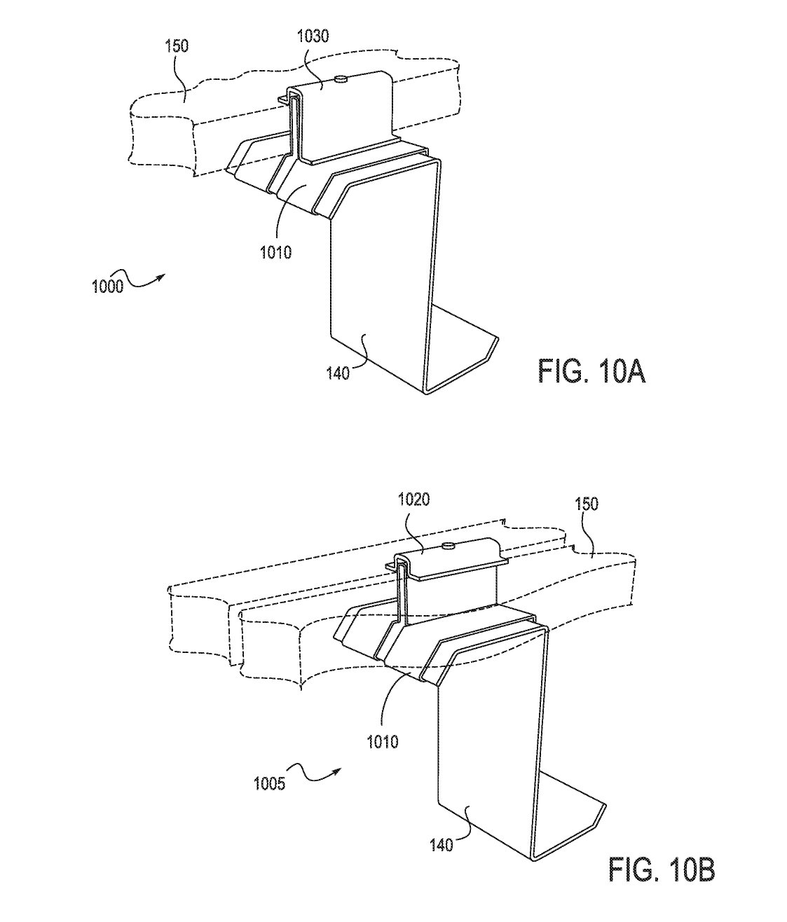

FIGS. 10A and 10B show cross-sectional perspective views in one embodiment of a clip assembly for attaching solar panels to zee channels, at the end of and in the middle of the solar canopy array, respectively, in the embodiment of FIG. 1. FIG. 10B depicts a cross-section of zee channels 140. A clip assembly comprising anchor member 1010 and head member 1020 sandwich edge portions of two solar power panels, i.e., the individual solar panels which make up solar power array 150. FIG. 10A shows a clip assembly sandwiching an edge portion of a single solar panel. This would occur at each end of a solar power array 150.

In both FIGS. 10A and 10B, anchor member 1010 is supported by zee channel 140. In a preferable embodiment anchor member 1010 is removably attached to zee channel 140, e.g., by a screw or bolt and nut (not shown).

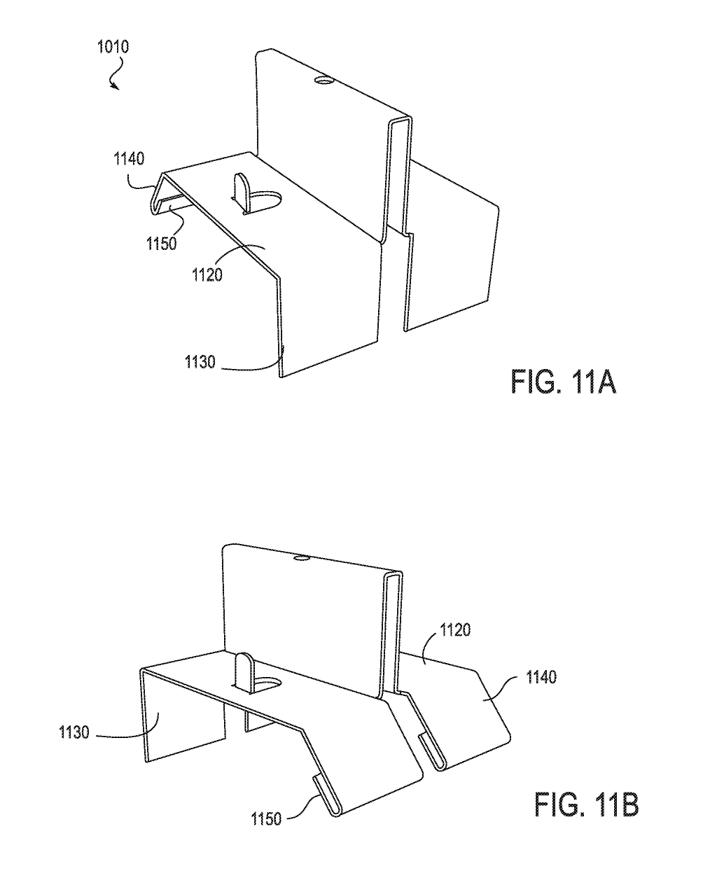

FIGS. 11A and 11B show perspective views of one embodiment of an anchor member for attaching solar panels to zee channels in one embodiment of FIG. 1. With reference to FIGS. 10A, 10B, 11A, and 11B, a planar section 1120 of the anchor member rests on the more horizontally oriented portion of the zee channel 140. A riser section 1130 of the anchor member rests against the more vertically oriented portion of the zee channel 140. An angled kick section 1140 rests against the more angled portion of the zee channel 140. Angled hook section 1150 of zee channel 140 hooks around the edge portion of the more angled portion of the zee channel 140. The angled hook section 1150 together with riser section 1130 secures the anchor member from movement perpendicularly to the longitudinal axis of zee channel 140. A screw or nut and bolt are preferably installed through both the anchor member and the zee channel 140 to prevent any movement along the longitudinal axis of the zee channel 140.

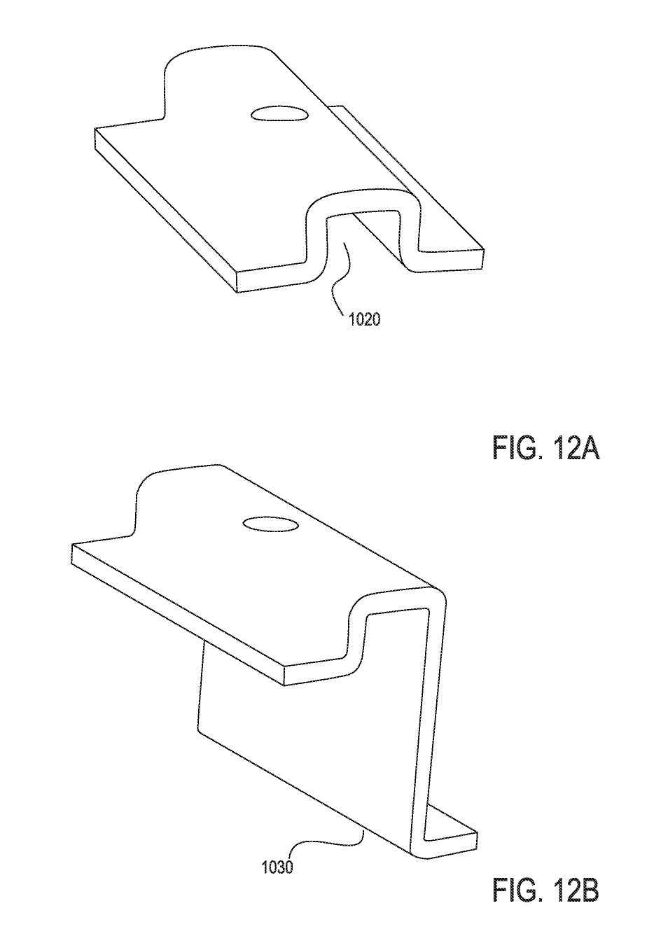

FIGS. 12A and 12B show perspective views in one embodiment of a head member of a clip assembly for attaching solar panels, at a middle section of and at an end section of the solar canopy array, respectively, to zee channels in the embodiment of FIG. 1. The head member is removably attached, e.g., via bolt or screws to the anchor member, which results in sandwiching the solar panels in between the head member (1020 or 1030) and anchor members 1140 of the clip assembly.

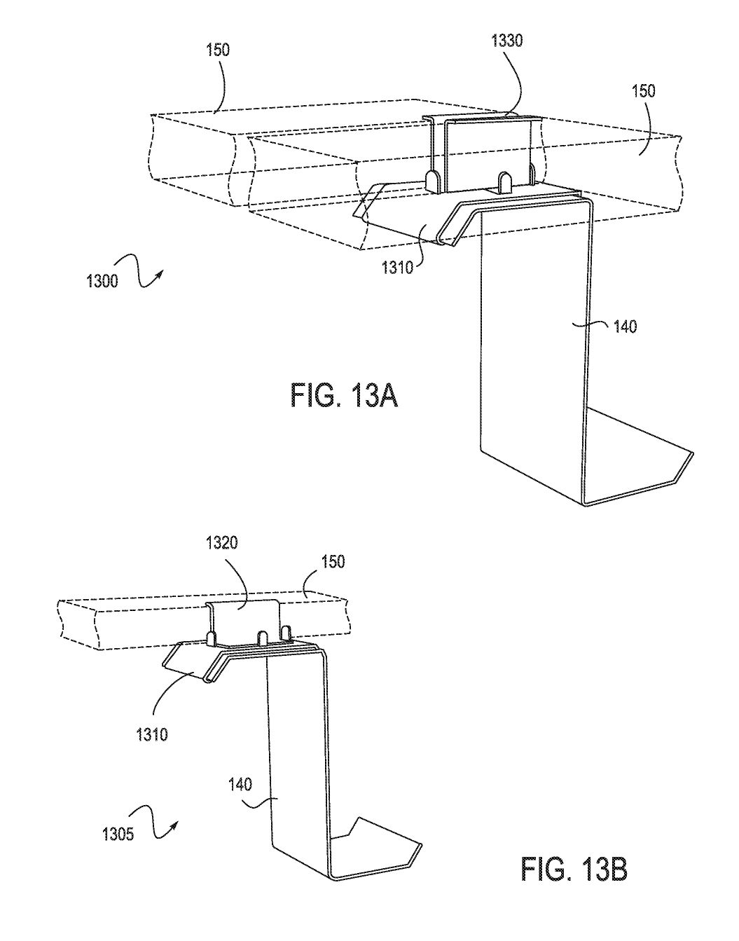

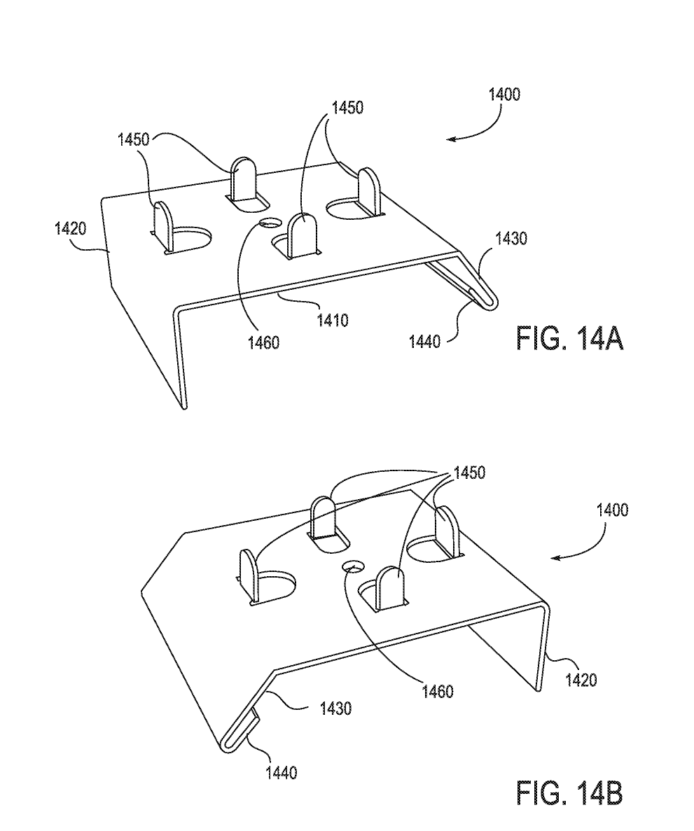

FIGS. 13A and 13B show perspective views in one preferred embodiment of a clip assembly for attaching solar panels to zee channels, at a middle section of and at an end section of the solar canopy array, respectively, in the embodiment of FIG. 1. FIGS. 14A and 14B show a top perspective view in another embodiment of an anchor member of a clip assembly for attaching solar panels to zee channels in the embodiment of FIG. 1. With reference to FIGS. 13A, 13B, 14A, and 14B, a planar section 1420 of the anchor member rests on the more horizontally oriented portion of the zee channel 140. A riser section 1420 of the anchor member rests against the more vertically oriented portion of the zee channel 140. An angled kick section 1430 rests against the more angled portion of the zee channel 140. Angled hook section 1440 of zee channel 140 hooks around the edge portion of the more angled portion of the zee channel 140.

The angled hook section 1440 together with riser section 1420 secures the anchor member from movement perpendicularly to the longitudinal axis of the zee channel 140. A screw or nut and bolt are preferably installed through both the anchor member and the zee channel 140 to prevent any movement along the longitudinal axis of the zee channel 140. In a preferable embodiment a bottom portion of tab sections 1450 are attached to and substantially perpendicular to planar section 1420. In a preferable embodiment tab section 1450 are integral with planar section 1420. The two tab sections 1450 along the lateral axis of the anchor member 1310 are for providing proper spacing between the solar panels, i.e., to allow joining of the head member (1330 or 1320) and anchor member 1310. The two tab sections 1450 along the longitudinal axis of the anchor member 1310 are for aligning the solar panels by engaging in recesses (not shown) in the bottom of the solar panels as they rest on the zee channels 140.

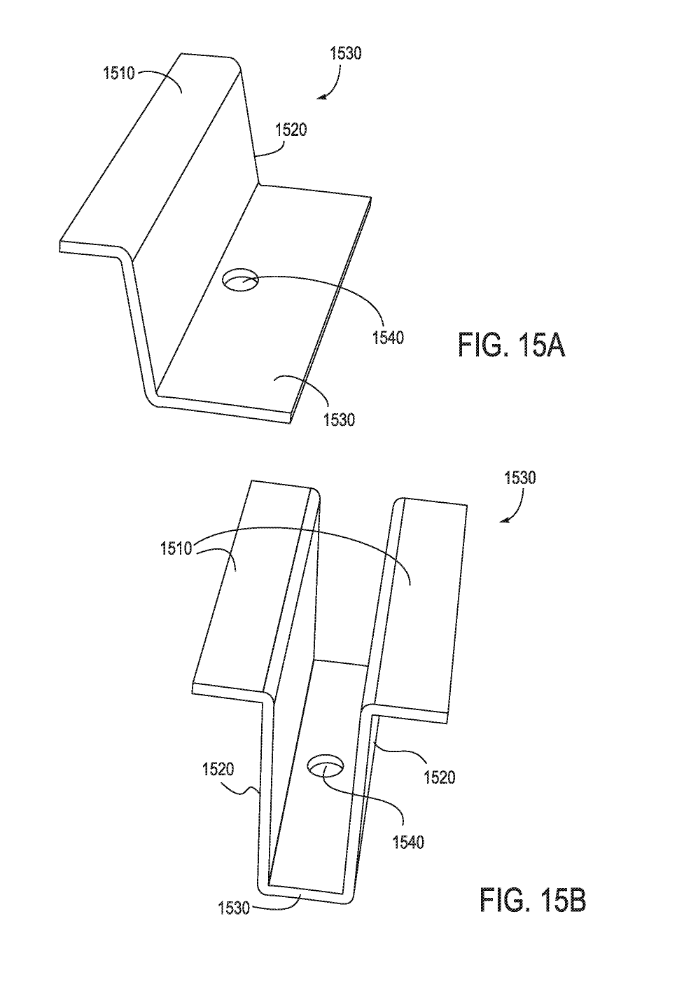

FIGS. 15A and 15B show perspective views in another embodiment of a head member 1530 or 1520 of a clip assembly for attaching solar panels, at an end section of and at a mid-section of the solar canopy array, respectively, to zee channels in the embodiment of FIG. 1.

The head member 1530 or 1520 is for clamping two solar panels between a bottom portion of the head member 1530 or 1520 and a top portion of the anchor member 1400. The head member is an elongated form including a plurality of sections. The sections include two substantially vertical planar riser sections 1520, each having a top end and a bottom end and being substantially parallel to each other. There is also a substantially horizontal joiner section 1530, for joining the two riser sections, having a left end and a right end, the left end of the joiner section adjoining the bottom end of one riser section, and the right end of the joiner section adjoining the bottom end of the other riser section, thereby forming a U-like assembly.

Also, there are two substantially horizontal planar clamping sections 1510, for clamping solar panels, each having a left end and a right end, the left end of one clamping section adjoining the top end of one riser section 1520, and the right end of the other clamping section adjoining the top end of the other riser section 1520; thereby forming a U-like assembly with flanges extending from the two top portions of the U-like assembly.

The head member 1530 or 1520 is removably fixed to the anchor member 1400, wherein a bottom portion of the solar power arrays rests on a top portion of the planar step section 1410 of the anchor member 1400, and a bottom portion of the planar clamping sections 1510 of the head member 1530 or 1520 rests on a top portion of the solar power arrays 150 (FIG. 1), thereby clamping the two solar power arrays to the zee channel 140 (FIG. 1).

The head member 1520 (FIG. 15B) or 1530 (FIG. 15A) is removably attached, e.g., via bolt or screws to the anchor member through, preferably threaded, hole 1540 in head member 1530 and 1520 and, preferably threaded, hole 1460 in anchor member 1400, thus sandwiching the solar panels in between the head member (1520 or 1530) and anchor members 1400 (FIGS. 14A and 14B) of the clip assembly.

Anchor member 1400, in one embodiment is comprised of 14 to about 18 gauge sheet metal. Head members 1520 or 1530, in one embodiment are comprised of 12 to about 14 gauge sheet metal. In addition to sheet metal, either the head member or anchor member may be fabricated by other known materials and fabrication methods such as a cast metal, e.g., cast aluminum. Typical dimensions of the anchor member are from about 3.0″ to about 4.0″ wide, from about 3.5″ to about 4.5″ long, and from about 1″ to about 3″ tall. Typical dimensions of the head member are from about 1″ to about 3″ wide, from about 2″ to about 3″ long, and from about 1″ to about 3″ tall. These dimensions are not meant to limit the invention and the head member and anchor member in various embodiments may be adjusted to fit a wide variety of zee channels and solar panels.

Other embodiments of the present invention and its individual components will become readily apparent to those skilled in the art from the foregoing detailed description. As will be realized, the invention is capable of other and different embodiments, and its several details are capable of modifications in various obvious respects, all without departing from the spirit and the scope of the present invention. Accordingly, the drawings and detailed description are to be regarded as illustrative in nature and not as restrictive. It is therefore not intended that the invention be limited except as indicated by the appended claims.

1. A solar canopy support system comprising:
(a) at least two substantially horizontally disposed zee channel support beams for supporting at least two zee channels, and
(b) at least two zee channels for supporting at least one solar power array and fixedly attached to the at least two zee channel support beams, each zee channel having a first end disposed at an upper portion of one zee channel support beam and having a second end disposed at an upper portion of another zee channel support beam, each zee channel comprising a longitudinal axis substantially perpendicular to the longitudinal axis of each zee channel support beam.

2. The solar canopy support system of claim 1, wherein each zee channel is longitudinally oriented opposite to the longitudinally orientation of each adjacent zee channel.

3. A solar canopy support system comprising:
(a) at least two beam support columns, each beam support column having a first end connected to a ground surface and extending substantially vertically along a longitudinal axis from the first end to a second end;
(b) a zee channel support beam disposed at the second end of each beam support column, the zee channel support beam comprising a longitudinal axis within about 0 degrees to about 30 degrees of perpendicular to the longitudinal axis of each beam support column;
(c) at least two zee channels, each zee channel having a first end disposed at an upper portion of one zee channel support beam and having a second end disposed at an upper portion of another zee channel support beam, each zee channel comprising a longitudinal axis substantially perpendicular to the longitudinal axis of each zee channel support beam;
(d) at least one solar power array disposed on an upper portion of the at least two zee channels.

4. (canceled)

5. The solar canopy support system of claim 1, wherein each beam support column is removably attached to a reinforced concrete bollard disposed in the ground.

6. The solar canopy support system of claim 3, further comprising a flange disposed at the first end of each beam support column for removably attaching the first end of each beam support column to the reinforced concrete bollard.

7. The solar canopy support system of claim 1, Wherein the zee channel support beam is removably attached at the second end of each beam support column.

8. The solar canopy support system of claim 5, further comprising a flange disposed substantially perpendicular to the longitudinal axis of the beam support column at the second end of each beam support column for removably attaching the second end of the beam support column to the zee channel support beams.

9. The solar canopy support system of claim 1, wherein each zee channel support beam is disposed substantially parallel to one another.

10. The solar canopy support system of claim 1, wherein each solar power array is disposed on an upper portion of at least two zee channels.

11. The solar canopy support system of claim 1, wherein a mid-portion of each zee channel support beam is disposed substantially at the second end of each beam support column.

12. The solar canopy support system of claim 1, wherein each zee channel is disposed in a reverse orientation to each adjacent zee channel.

13. The solar canopy support system of claim 10, wherein each solar power array is disposed on an upper portion of two zee channels and wherein an upper edge portion of the upper portion of each zee channel is facing inward toward a space between the two zee channels.

14. The solar canopy support system of claim 1, further comprising at least two zee channel attachment flanges disposed on an upper portion of each zee channel support beam, the zee channel attachment flanges having a longitudinal axis disposed substantially perpendicular to the longitudinal axis of the see channel support beam, for attaching the zee channels.

15. The solar canopy support system of claim 12, wherein each zee channel is removably attached to zee channel attachment flanges integral with the zee channel support beams.

16. A method of mounting a solar canopy comprising:
(a) affixing at least two beam support columns to a ground surface, each beam support column having a first end connected to the ground surface and extending substantially vertically along a longitudinal axis from the first end to a second end;
(b) affixing a zee channel support beam to the second end of each beam support column, the zee channel support beam comprising a longitudinal axis within about 0 degrees to about 30 degrees of perpendicular to the longitudinal axis of each beam support column;
(c) affixing at least two zee channels to the at least two zee channel support beams, each zee channel having a first end disposed at an upper portion of one zee channel support beam and having a second end disposed at an upper portion of another zee channel support beam, each zee channel comprising a longitudinal axis substantially perpendicular to the longitudinal axis of each zee channel support beam;
(d) affixing at least one solar power array to an upper portion of the at least two zee channels.

17. The method of claim 16, wherein each beam support column is removably attached to a reinforced concrete bollard disposed in the ground.

18. The method of claim 16, wherein the zee channel support beam is removably attached at the second end of each beam support column.

19. (canceled)

20. The method of claim 16, wherein each solar power array is disposed on an upper portion of at least two zee channels.

21. The solar canopy support system of claim 20, wherein each zee channel is disposed in a reverse orientation to each adjacent zee channel.

22. The solar canopy support system of claim 16, wherein each solar power array is disposed on an upper portion of two zee channels and wherein an upper
